(19) United States
(12) Patent Application Publication
(10) Pub. No.: US 2008/0045015 A1
(43) Pub. Date: Feb. 21, 2008

(54) Method of etching wafer

(75) Inventor: Kazuma Sekiya, Ota-ku (JP)

Correspondence Address: GREER, BURNS & CRAIN, 300 S WACKER DR, 25TH FLOOR, CHICAGO, IL, 60606, US

(73) Assignee: Disco Corporation, Tokyo (JP)

(21) Appl. No.: 11/891,244

(22) Filed: Aug. 9, 2007

(30) Foreign Application Priority Data
Aug. 16, 2006 (JP) 2006-221853

(51) Int. Cl. H01L 21/302

(52) U.S. Cl. 438/691; 257/E21.214

(57) ABSTRACT

A method of etching a wafer includes the steps of holding the wafer on a chuck table in the condition where a recessed part formed in the wafer by grinding is directed up, and supplying a required amount of an etchant into the recessed part to perform etching. Subsequently, the wafer is rotated together with the chuck table, the etchant in the recessed part is removed by scattering it away by a centrifugal force, and thereafter pure water is supplied to the recessed part, in the condition where the chuck table is kept rotating, so as to clean the recessed part.

### BACKGROUND OF THE INVENTION

1. Field of the Invention

The present invention relates to a method of etching a wafer for securing strength of the wafer, for example a semiconductor wafer, through removing mechanical damages left in a ground surface of a recessed part formed on the back side of the wafer by applying back-side grinding to only a part corresponding to a device forming region of the wafer.

2. Description of the Related Art

Such devices as semiconductor chips used for various electronic apparatuses are generally manufactured by a method in which the back side of a circular disk-shaped semiconductor wafer is partitioned into rectangular regions in a lattice pattern by forming planned split lines called “streets”, and, after the formation of electronic circuits on the face side of these regions, the back side of the wafer is ground to achieve thinning, and the wafer is split along the streets. Meanwhile, electronic apparatuses have been showing a conspicuous trend toward smaller sizes and thinner forms in recent years, attended by an increasing demand for thinner semiconductor chips and, hence, an increasing demand for thinner semiconductor wafers.

However, thinning of a semiconductor wafer lowers the rigidity of the wafer, making the wafer difficult to handle in subsequent steps or liable to crack. To obviate this problem attendant on thinning of a wafer, the back-side grinding of the wafer is sometimes carried out by a method in which only the back-side part corresponding to a circular device forming region on the face side where semiconductor chips are formed is ground to a desired thickness to achieve the thinning, and, simultaneously, an annular peripheral surplus region in the periphery of the part thus ground is left as a comparatively thick reinforcing part. The technology for forming a recessed part on the back side of a wafer while leaving a thicker peripheral part in this manner is disclosed, for example, in Japanese Patent Laid-open No. 2004-281551 or Japanese Patent Laid-open No. 2005-123425.

In the technology described in Japanese Patent Laid-open No. 2004-281551, the recessed part on the back side of a wafer is formed by etching, polishing, or sandblasting. However, use of these means requires a long processing time for attaining the desired thickness, and is therefore inefficient. Especially, etching needs a special masking step, which leads to a lowered productivity. On the other hand, Japanese Patent Laid-open No. 2005-123425 describes a method in which most of the recessed part is first formed by abrasive blasting and/or etching, and thereafter the recessed part is finished by polishing. However, this method also takes a long time to form the recessed part. Moreover, the polishing requires preparation of a special polishing tool having a diameter smaller than the diameter of the recessed part, which is disadvantageous on a cost basis.

In view of the above, as an effective means for forming such a recessed part, a grinding technique has been contemplated in which a grindstone in high-speed rotation is pressed against a recessed part forming surface on the back side of a wafer so as to achieve the desired thinning. Use of grinding has the merit of comparatively speedy formation of the recessed part. However, since grinding streaks are left as mechanical damages, the wafer as ground shows a lowered mechanical strength, so that it is necessary to remove the mechanical damages by mirror-surface finishing the ground surface. While plasma etching or polishing may be selected for the finishing treatment, there is a keen demand for a method of finishing treatment which promises an easy treatment and an enhanced productivity.

### SUMMARY OF THE INVENTION

Accordingly, it is an object of the present invention to provide a method of etching a wafer by which a finishing treatment of a recessed part formed on the back side of a wafer by grinding can be carried out easily and inexpensively, promising an enhanced productivity.

In accordance with an aspect of the present invention, there is provided a method of etching a wafer, for applying chemical etching to a recessed part of a wafer having on a face side thereof a peripheral surplus region in the periphery of a device forming region provided with a plurality of devices, a region on the back side of the wafer corresponding to the device forming region being thinned by grinding, the recessed part being formed on the back side of the wafer, and the wafer being provided in the peripheral surplus region with an annular projected part projected to the back side thereof, the method including the steps of: holding the wafer on a rotatable holding means, with the recessed part exposed to the upper side; supplying a required amount of an etchant into the recessed part to perform etching; rotating the holding means so as to rotate the wafer and to thereby remove the etchant in the recessed part by scattering the etchant away to the outside of the recessed part by a centrifugal force; and supplying a cleaning liquid to the recessed part, in the condition where the holding means is kept rotating, so as to clean the recessed part.

In the present invention, a required amount of the etchant is placed in the recessed part, and this condition is kept for a predetermined period of time, whereby a bottom surface and an inner peripheral surface of the recessed part are etched. After the etching, the wafer is rotated together with the holding means to scatter the etchant away out of the recessed part, thereby removing the etchant. Thereafter, with the wafer kept rotating, a cleaning liquid such as pure water is supplied into the recessed part so as to clean the recessed part with the spinning-out etchant.

According to the present invention, etching can be conducted by supplying the etchant into the recessed part, without immersing the wafer in the etchant. Therefore, only the recessed part can be securely etched without masking the face side of the wafer or the peripheral surplus region, and the amount of the etchant used can be suppressed to a minimum amount. Accordingly, the etching can be carried out easily and inexpensively. After the etching step, the etchant can be removed by scattering it away through rotating the wafer, and the recessed part can be cleaned by supplying the cleaning liquid into the recessed part while keeping the rotation of the wafer. In the present invention, the process ranging from the etching to the cleaning can be smoothly conducted through a series of steps while holding the wafer on the holding means, whereby an enhanced productivity is promised.

When sufficient etching can be achieved by supplying the etchant only once, the etchant removing step and the cleaning step may be conducted subsequent to the etching step. On the other hand, in the case where sufficient etching cannot be achieved with that amount of the etchant which is present in the recessed part, it may be necessary to repeat the etching by replacing the used etchant with a fresh etchant. In that case, the etching step and the etchant removing step are repeated the predetermined number of times, and thereafter the cleaning step is conducted.

Besides, in the present invention, preferably, the rotating speed of the holding means in the cleaning step is set to be lower than the rotating speed of the holding means in the etchant removing step. The viscosity of the etchant is generally higher than that of the cleaning liquid (for example, pure water). Therefore, if the rotating speed of the wafer in the cleaning step is equal to or higher than the rotating speed in the step of removing the etchant by scattering it away, the cleaning liquid would be scattered away before mixing well with the etchant, so that the cleaning effect is lowered. In view of this, the rotating speed of the wafer, i.e. of the holding means, in the cleaning step is set lower than that in the etchant removing step, whereby it is ensured that the dwelling time of the cleaning liquid is prolonged, the cleaning liquid is permitted to mix well with the etchant, and the cleaning effect can be thereby enhanced.

According to the present invention, the treatments ranging from etching to cleaning of the recessed part formed in a wafer by grinding can be carried out smoothly through a series of steps while keeping the wafer held by the holding means. Therefore, the finishing treatment of the recessed part can be carried out easily and inexpensively, whereby an enhanced productivity is promised.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view of a wafer of which a recessed part on the back side is etched by the etching method according to an embodiment of the present invention after the formation of the recessed part;

FIG. 1B is a side view of the same;

FIG. 2A is a side view of a wafer grinding apparatus;

FIG. 2B is a plan view of the same;

FIG. 3A is a perspective view of a wafer provided with a recessed part on the back side thereof by the wafer grinding apparatus;

FIG. 3B is a sectional view of the same;

FIG. 4 is a perspective view of an etching apparatus with which the etching method according to the embodiment can be carried out favorably;

FIG. 5 is a side view showing a tip part of a transfer arm of the etching apparatus; and

FIGS. 6A to 6C are side views illustrating the etching treatment according to the embodiment in the sequence of steps.

### DETAILED DESCRIPTION OF THE PREFERRED EMBODIMENTS

Now, wafer processing steps to which an etching method according to an embodiment of the present invention is applied will be described below, referring to the drawings.

[1] Semiconductor Wafer

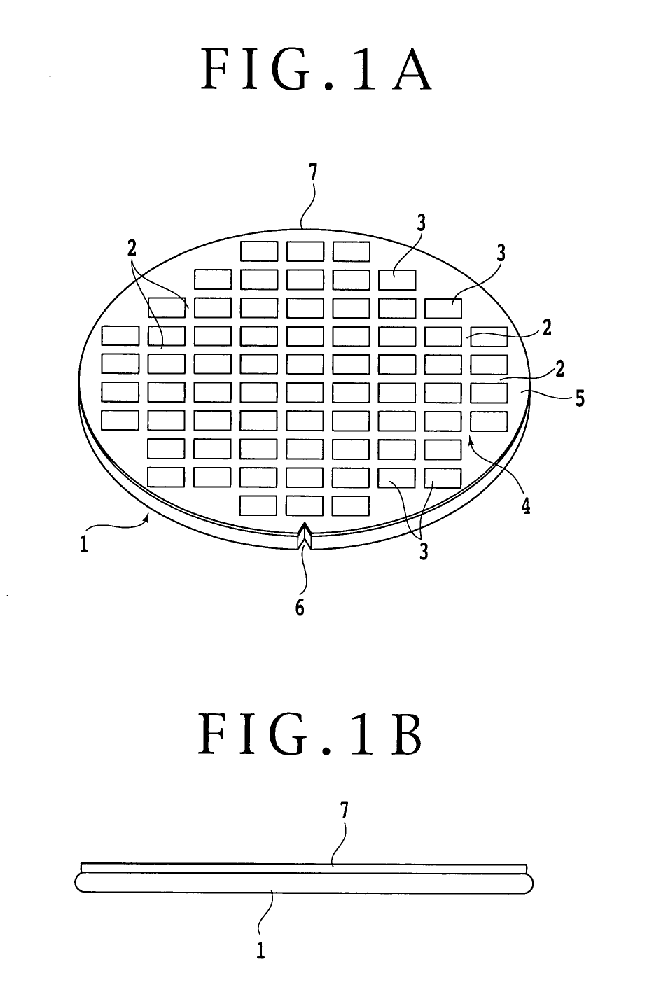

FIGS. 1A and 1B show a circular disk-shaped semiconductor wafer (hereinafter referred to simply as wafer) formed with a recess on the back side thereof. The wafer 1 is a silicon wafer or the like, and the thickness thereof before processing is, for example, about 600 to 700 μm. On the face side of the wafer 1, a plurality of rectangular semiconductor chips (devices) 3 are partitioned by planned split lines 2 formed in a lattice pattern. An electronic circuit (not shown) such as IC and LSI is formed on the face side of each of the semiconductor chips 3.

The plurality of semiconductor chips 3 are formed in a device forming region 4 having a generally circular shape concentric with the wafer 1. The device forming region 4 occupies most part of the wafer 1, and a wafer peripheral part in the periphery of the device forming region 4 is an annular peripheral surplus region 5 in which the semiconductor chips 3 are not formed. In addition, the circumferential surface of the wafer 1 is provided at a predetermined position with a V-shaped notch 6 indicative of the crystal orientation of the semiconductor constituting the wafer. The notch 6 is formed in the peripheral surplus region 5. After the device forming region 4 is thinned, the wafer 1 is finally cut and split along the planned split lines 2, to be diced into the plurality of semiconductor chips 3.

At the time of grinding the back side of the wafer 1, a protective tape 7 is adhered to the face side on which the electronic circuits have been formed, as shown in FIGS. 1A and 1B, for the purpose of protecting the electronic circuits and the like purpose. The protective tape 7 may be, for example, one having a configuration in which one side of a polyethylene or polyolefin sheet having a thickness of about 100 to 200 μm is coated with a pressure sensitive adhesive in a thickness of about 10 μm.

[2] Formation of Recessed Part on the Back Side

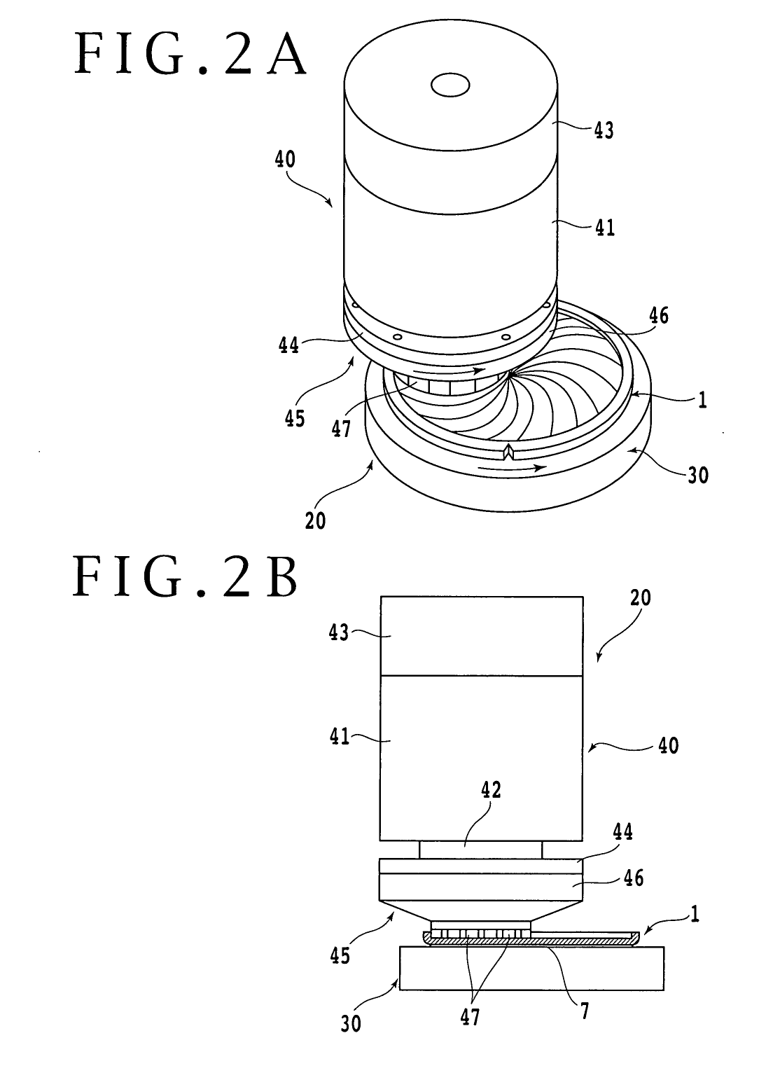

Next, only the region, corresponding to the device forming region 4, of the back side of the wafer 1 is thinned by grinding so as to form a recessed part on the back side of the wafer 1. FIGS. 2A and 2B show a grinding apparatus 20 suitable for forming the recessed part. The grinding apparatus 20 includes a vacuum chuck type chuck table 30 for holding the wafer 1, and a grinding unit 40 disposed on the upper side of the chuck table 30.

The grinding unit 40 includes a hollow cylindrical spindle housing 41 with its axis extending along the Z direction, a spindle 42 supported coaxially and rotatably in the spindle housing 41, a motor 43 fixed to an upper end part of the spindle housing 41 and operative to rotatingly drive the spindle 42, and a circular disk-shaped flange 44 coaxially fixed to the lower end of the spindle 42. In addition, a cup wheel 45 is detachably attached to the flange 44 by such means as screwing.

The cup wheel 45 has a frame 46 having a circular disk-like shape with a lower part being conical, and a plurality of grindstones 47 arranged and fixed in an annular pattern along the whole circumference of a peripheral part of the lower end face of the frame 46. The grindstones 47 may be, for example, those obtained by firing a mixture of a vitreous (so-called vitrified) sintering material with diamond abrasive grains. For grinding the wafer, grindstones containing abrasive grains of a grain size of about #280 to #8000 mixed therein are preferably used. As shown in FIG. 2B, the grinding outside diameter of the cup wheel 45, i.e., the diameter of the outer circumferential edge of the plurality of grindstones 47 is set to be substantially equal to or slightly larger than the radius of the device forming region 4 of the wafer 1.

According to the grinding apparatus 20 as above, the wafer 1 is sucked and held onto the chuck table 30, concentrically with the chuck table 30, in the condition where its face side with the protective tape 7 adhered thereto is put in close contact with the top face of the chuck table 30 and its back side is exposed to the upper side. In this condition, the chuck table 30 is rotated. Then, the grinding unit 40 as a whole is lowered, and, while the cup wheel 45 is rotated at a rate of about 2000 to 5000 rpm, the grindstones 47 is pressed against the region, corresponding to the device forming region 4, of the back side of the wafer 1, whereby the region is ground and thinned. Incidentally, during the grinding step, grinding water is supplied to the surface to be ground of the wafer 1.

The grindstones 47 of the cup wheel 45 are located relative to the wafer 1 in such a manner that the locus of grinding thereof ranges from the peripheral edge of the device forming region 4 (the boundary line between the device forming region 4 and the peripheral surplus region 5) to slightly beyond the center of the wafer 1. This ensures that only the region, corresponding to the device forming region 4, of the back side of the wafer 1 is ground and thinned.

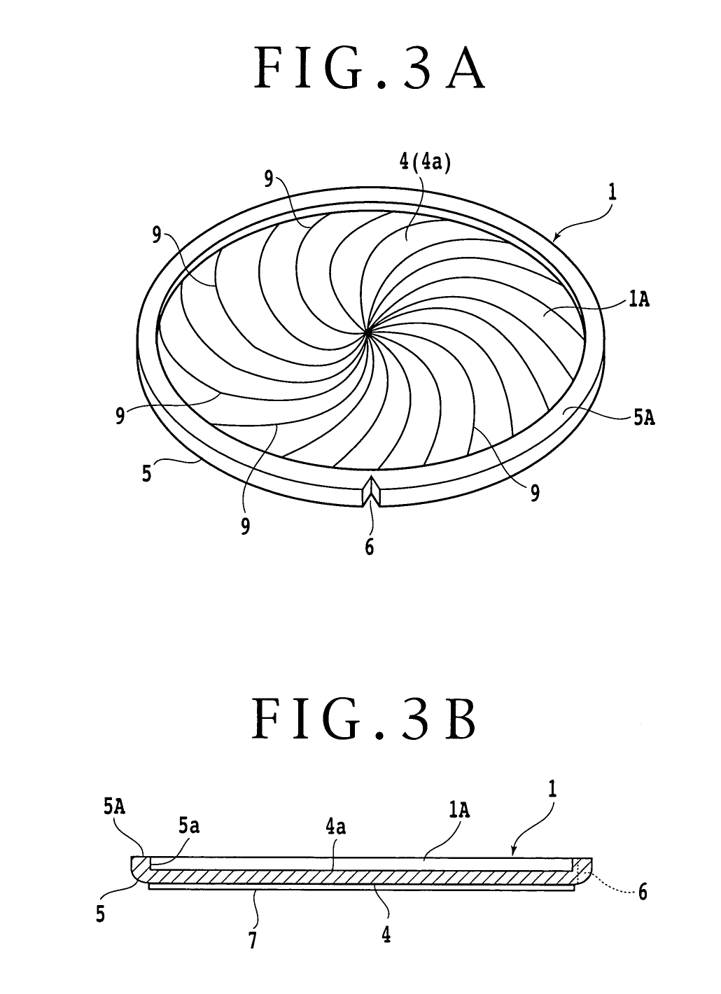

When the region, corresponding to the device forming region 4, of the back side of the wafer 1 is ground and thinned to an objective thickness (for example, about 200 to 100 μm, or about 50 μm), the grinding unit 40 is raised to separate the grindstones 47 from the wafer 1, and the rotation of the chuck table 30 is stopped. On the back side of the wafer 1, a recessed part 1A is formed, by the grinding, in the region corresponding to the device forming region 4 as shown in FIGS. 3A and 3B. Simultaneously, an annular projected part 5A projected to the back side with the original thickness left is formed in the region of the back side of the wafer 1. Thus, the wafer 1 as a whole is processed to have a recessed sectional shape.

As shown in FIG. 3A, grinding streaks 9 upon grinding by the grindstones 47, in the shape of a multiplicity of arcs extending radially from the center, are left in the bottom surface 4a of the recessed part 1A. The grinding streaks 9 are loci of crushing by the abrasive grains present in the grindstones 47, and constitute a layer of mechanical damages including microcracks. Similar damages are formed also in the inner circumferential surface 5a of the annular projected part 5A. These mechanical damages are removed in the subsequent etching step.

[3] Etching Treatment

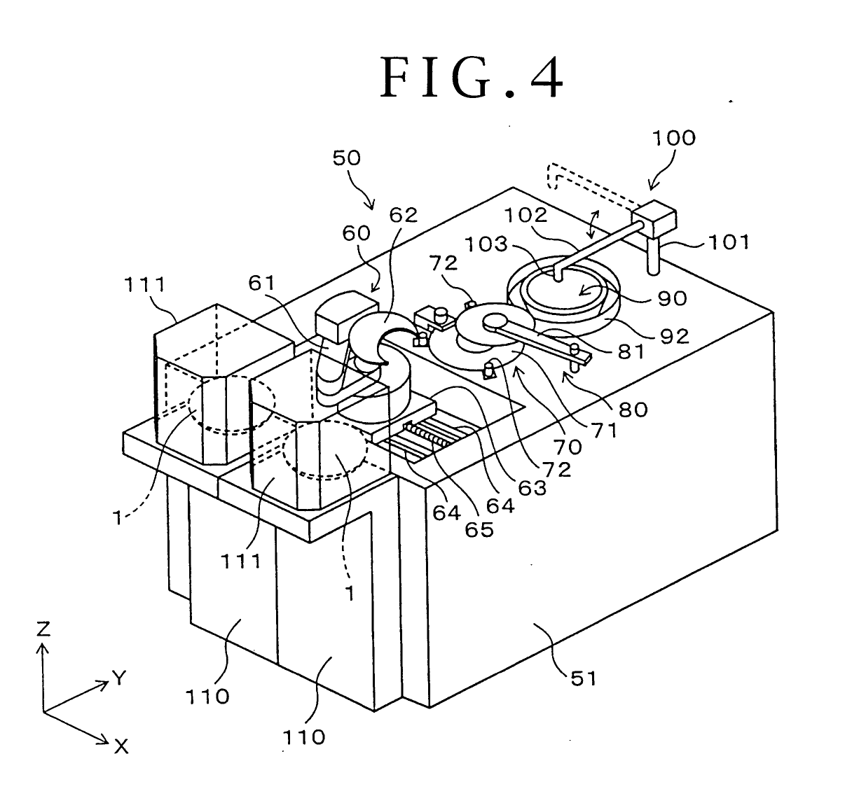

Next, an etching treatment for etching the back side of the wafer 1 so as to remove, by some thickness, the bottom surface 4a of the recessed part 1A and the inner circumferential surface 5a of the annular projected part 5a is conducted. The etching method described below is according to the present invention, and FIG. 4 shows an etching apparatus with which the etching method can be carried out suitably. The etching apparatus 50 has a rectangular parallelopiped base 51. A pick-up robot 60, a positioning table 70 and a transfer arm 80, a chuck table (holding means) 90, and an ethant supplying device 100 are arranged on the base 50 in this order from one end side toward the other end side along the Y direction in the figure, i.e., along the longitudinal direction of the base 50.

On one end side of the base 51, a pair of cassette stages 110 are arranged side by side in the X direction, and cassettes 111 are placed on the cassette stages 110. Each of the cassettes 111 accommodates a multiplicity of wafers 1 in a stacked condition. One of the cassettes 111 may be used as a supply-side cassette in which a multiplicity of cassettes 1 are contained, and the other of the cassettes 111 may be used as a recovery-side cassette which is empty in the beginning and into which the wafers 1 provided with the recessed part 1A are sequentially contained. Or, alternatively, the wafers 1 provided with the recessed part 1A may be returned into their original slots in the supply-side cassette 111. In the supply-side cassette 111, a multiplicity of wafers 1 with the protective sheets 7 adhered to the face side thereof are stacked in the condition where the back side thereof not covered with the protective sheet 7 is directed up. Each of the cassettes 111 is detachably mounted on the cassette stage 110 in the condition where a wafer inlet/outlet port opening to one lateral side thereof is directed toward the base 51 side.

The pick-up robot 60 has a configuration in which a pick 62 for gripping the wafer 1 is mounted to the tip of a two-node link 61 which can be moved up and down. The pick-up robot 60 is mounted on the base 51 to be movable in the X direction through a slider 63. In addition, a screw rod 65 extending in the X direction and disposed between guide rails 64 penetrates the slider 63 in a screw engaged manner. The screw rod 65 is rotated normally and reversely by a motor (not shown), whereon the pick-up robot 60 is moved in the X direction along the guide rails 64 through the slider 63, by a moving force produced by the screw rod 64 rotated by the motor. The pick-up robot 60 functions to take one wafer 1 out of the supply-side cassette 111 and transfer the wafer 1 onto the positioning table 70, and to insert into the recovery-side cassette 111 the processed wafer 1 transferred onto the positioning table 70.

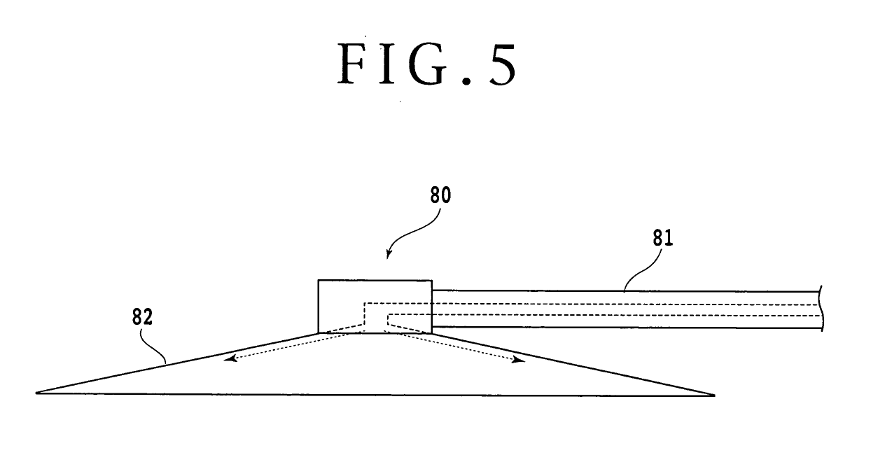

The positioning table 70 is for positioning the wafer 1 by a method in which the wafer 1 mounted on a disk table 71 is moved toward the center of the disk table 71 by a plurality of pins 72. The transfer arm 80 is for transferring the wafer 1 between the positioning table 70 and the chuck table 90. As shown in FIG. 5, the transfer arm 80 has a configuration in which a suction pad 82 for sucking the wafer 1 by Bernoulli type suction is attached to the tip of a slewing arm 81. The wafer 1 positioned onto the positioning table 70 is sucked onto the suction pad 82 of the transfer arm 80, and is mounted substantially concentrically onto the circular disk-shaped chuck table 90 by the slewing arm 81.

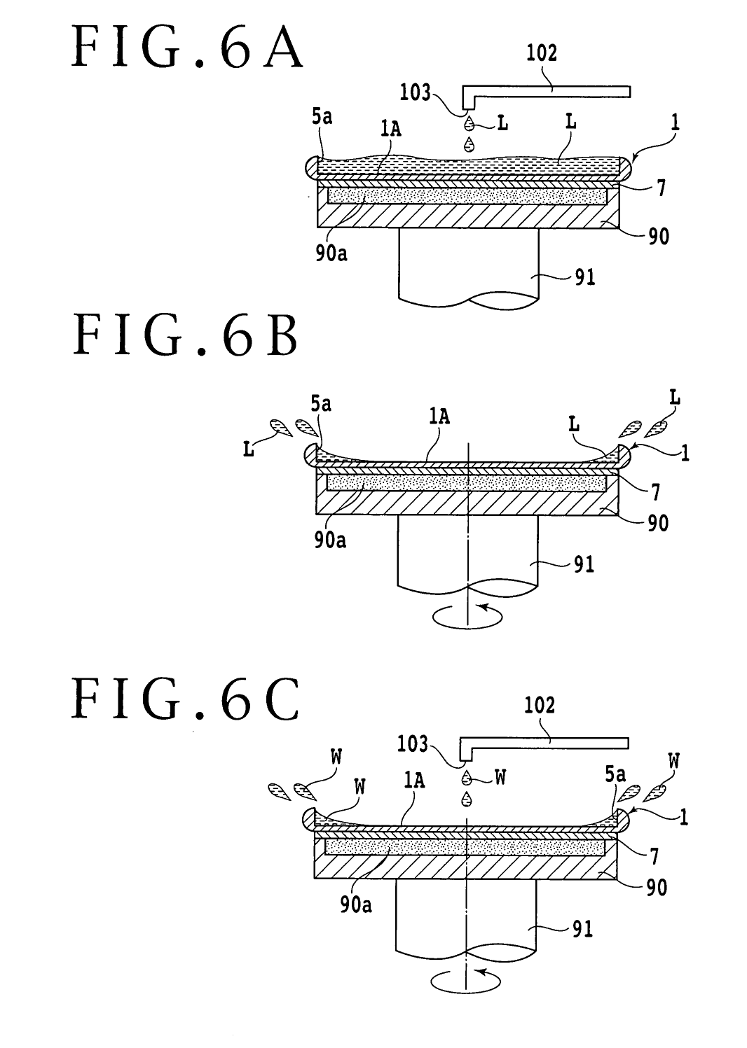

The chuck table 90 is supported on a rotating shaft 91 shown in FIG. 6A, and the rotating shaft 91 is rotated by a rotational driving mechanism (not shown). A horizontal top surface of the chuck table 90 is provided with a suction area 90a for sucking the wafer 1 by air suction. An annular shutter wall 92 is fixed in the periphery of the chuck table 90, and the inside of the shutter wall 92 forms an etching area.

The etchant supply device 100 has a configuration in which a liquid supply pipe 102 extending horizontally is fixed to a shaft 101 rotatably erected on the base 51. The etchant supply device 100 is slewed horizontally by a rotational driving mechanism (not shown). A nozzle 103 for dropping an etchant is formed at the tip of the liquid supply pipe 102. By the rotation of the shaft 101, the nozzle 103 of the liquid supply pipe 102 is located into an etchant supplying position just above the center of rotation of the chuck table 90 and into a retracted position retracted from the etchant supplying position as indicated by broken line. The etchant supply device 100 is supplied not only with a predetermined etchant but also with pure water as a cleaning liquid used after etching. The liquid to be supplied is switchingly selected, and is fed from the shaft 101 through the liquid supply pipe 102, to be dropped from the nozzle 103.

With the etching apparatus 100 as above, the etching treatment of the wafer 1 is performed as follows. First, one wafer 1 is taken out of the supply-side cassette 111 by the pick-up robot 60, is transferred onto the positioning table 70 with its back side exposed to the upper side, and is positioned. The pick-up robot 60 is moved to an appropriate position through rising and falling operations and the movement of the slider 63. Subsequently, the wafer 1 is moved from the positioning table 70 onto the chuck table 90 by the transfer arm 80. The chuck table 90 is preliminarily operated with vacuum, so that the protective tape 7 is put into suction contact with the suction area of the chuck table 90, whereby the wafer 1 is held on the chuck table 90 (holding step).

Next, the liquid supply pipe 102 of the etchant supply device 100 is slewed to be located into the etchant supplying position, a predetermined etchant is supplied into the liquid supply pipe 102, and, as shown in FIG. 6A, the etchant L is dropped from the nozzle 103 into the recessed part 1A of the wafer 1, to fill up the recessed part 1A with the etchant L. Examples of the etchant L include a mixed acid prepared by mixing hydrofluoric acid with nitric acid, and a TMAH (tetramethylammonium hydroxide) solution. The etchant L is preferably warmed before used, since warming accelerates the etching consisting in a chemical reaction of the etchant with the wafer 1.

With the recessed part 1A supplied and filled up with the etchant L, the bottom surface 4a and the inner circumferential surface 5a of the recessed part 1A which are contacted by the etchant L are etched. Subsequently, after the lapse of an etching time set as needed, the chuck table 90 is rotated at a rate of, for example, about 1000 rpm, thereby rotating the wafer 1. In this instance, the liquid supply pipe 102 is preliminarily retracted into the retracted position. As a result, the etchant L in the recessed part 1A is scattered away outwards in the radial direction of the wafer 1 by a centrifugal force, as shown in FIG. 6B, to be removed from the inside of the recessed part 1A. The scattered etchant L collides on the shutter wall 92, to be prevented from scattering to the outside beyond the shutter wall 92.

The etching time for which the recessed part 1A is kept filled up with the etchant L is set to be, for example, not less than 60 seconds, in view of the fact that the back side is generally desirably a mirror finished surface for the purpose of enhancing the die-bonding properties of the semiconductor chip 3. Incidentally, in the case of manufacturing the semiconductor chip 3 as a power type device in which electrodes should be provided on both face and back sides, it may be necessary to make the back side rather a rough surface, in order to lower the contact resistance thereof; in such a case, the etching time is set to be about 30 seconds.

In the case where removal of the wafer material by a thickness desired cannot be achieved with the amount of the etchant L supplied in one-time etching which is continued for a comparatively long etching time, the wafer 1 is rotated to remove the etchant, then the rotation of the wafer 1 is stopped, and a fresh etchant L is again supplied into the inside of the recessed part 1A. With the supply and removal of the etchant L thus repeated an appropriate number of times, the required etching amount can be attained.

Next, while the wafer 1 is kept rotated, the liquid supply pipe 102 is again located into the etchant supplying position, the liquid to be supplied is switched from the etchant to pure water, and pure water W is dropped from the nozzle 103 to be supplied into the recessed part 1A, as shown in FIG. 6C. The etchant L left adhering to the bottom surface 4a and the inner circumferential surface 5a of the recessed part 1A is cleaned away by the pure water W thus supplied, and the resultant pure water W mixed with the etchant L is removed by scattering away from the wafer 1 being rotated (cleaning step).

Incidentally, the rotating speed of the chuck table 90 during the cleaning is preferably lower than the rotating speed in the etchant removing step, and is set to be, for example, about 500 rpm. When the rotating speed of the wafer 1 in the cleaning step is thus set to be lower than that in the etchant removing step, the highly viscous etchant L is mixed well into the pure water W, leading to an enhanced cleaning effect. In addition, the cleaning effect can by enhanced also by varying the rotating speed of the chuck table 90 or by abruptly stopping the rotation of the chuck table 90.

When the etchant left adhering to parts of the recessed part 1A is completely removed and the cleaning step is finished, the rotation of the chuck table 90 is stopped, and then the vacuum operation of the chuck table 90 is also stopped. Thereafter, the wafer 1 on the chuck table 90 is again transferred onto the positioning table 70 by the transfer arm 80, and is positioned. Next, the wafer 1 is moved from the positioning table 70 to be contained into the recovery-side cassette 111 by the pick-up robot 60. The above operations constitute one cycle of etching treatment, and the etching treatment of a multiplicity of wafers 1 is conducted by repeating the above-mentioned operations.

According to this embodiment, the recessed part 1A of the wafer 1 is etched by supplying the etchant L into the recessed part 1A, without immersing the wafer 1 in the etchant. Therefore, only the recessed part 1A can be assuredly etched without need for masking. In addition, the amount of the etchant L used can be suppressed to a minimum level. As a result, the etching can be carried out easily and at low cost.

In addition, after the etching step, the etchant L can be removed by scattering it away through rotating the wafer 1. Besides, the recessed part 1A can be cleaned by supplying pure water W (used as a cleaning liquid) into the recessed part 1A while keeping the rotation of the wafer 1. Thus, the treatments ranging from etching to cleaning can be smoothly carried out through a series of steps while keeping the wafer 1 held on the chuck table 90, which promises an enhanced productivity.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of etching a wafer, for applying chemical etching to a recessed part of a wafer having on a face side thereof a peripheral surplus region in the periphery of a device forming region provided with a plurality of devices, a region on the back side of said wafer corresponding to said device forming region being thinned by grinding, said recessed part being formed on the back side of said wafer, and said wafer being provided in said peripheral surplus region with an annular projected part projected to the back side thereof, said method comprising the steps of:
holding said wafer on a rotatable holding means, with said recessed part exposed to the upper side;
supplying a required amount of an etchant into said recessed part to perform etching;
rotating said holding means so as to rotate said wafer and to thereby remove said etchant in said recessed part by scattering said etchant away to the outside of said recessed part by a centrifugal force; and
supplying a cleaning liquid to said recessed part, in the condition where said holding means is kept rotating, so as to clean said recessed part.

2. The method of etching a wafer as set forth in claim 1, wherein said etching step and said etchant removing step are repeated a predetermined number of times, and thereafter said cleaning step is conducted.

3. The method of etching a wafer as set forth in claim 1, wherein the rotating speed of said holding means in said cleaning step is lower than the rotating speed of said holding means in said etchant removing step.
